(19) United States
(12) Patent Application Publication
(10) Pub. No.: US 2025/0069870 A1
(43) Pub. Date: Feb. 27, 2025

(54) Inductively Coupled Plasma Light Source

(71) Applicants: Hamamatsu Photonics K.K., Shizuoka (JP); Energetiq Technology, Inc., Wilmington, MA (US)

(72) Inventors: Stephen F. Horne, Medford, MA (US); Kosuke Saito, Hamamatsu-Shi (JP); Wolfram Neff, Wobum, MA (US); Robert M. Grzybinski, Gloucester, MA (US); Michael J. Roderick, Everett, MA (US)

(73) Assignees: Hamamatsu Photonics K.K., Shizuoka (JP); Energetiq Technology, Inc., Wilmington, MA (US)

(21) Appl. No.: 18/940,761

(22) Filed: Nov. 7, 2024

Related U.S. Application Data
(63) Continuation of application No. 17/676,712, filed on Feb. 21, 2022, now Pat. No. 12,165,856.

(51) Int. Cl. H01J 37/32

(52) U.S. Cl. CPC H01J 37/32935; H01J 37/32357; H01J 37/3244

(57) ABSTRACT

A plasma chamber for a UV light source includes a plasma generation region that defines a plasma confinement region. A port is positioned adjacent to a side of the plasma generation region that allows generated light to pass out of the chamber. A high voltage region is coupled to the plasma generation region. A grounded region is coupled to the high voltage region that defines an outer surface configured to be coupled to the ground and is dimensioned for receiving a surrounding inductive core. A width of the high voltage region is greater than the width of the grounded region.

The section headings used herein are for organizational purposes only and should not be construed as limiting the subject matter described in the present application in any way.

### INTRODUCTION

Numerous commercial and academic applications have a need for high brightness light in the extreme ultra-violet (EUV) region of the spectrum. For example, EUV light is needed for numerous industrial applications, including metrology, accelerated testing, photoresist, defect inspection, and microscopy. Other applications for EUV light include microscopy, spectroscopy, areal imaging, and blank mask inspection. These and other applications require EUV sources that have high reliability, small physical size, low fixed cost, low operating cost, and low complexity from these important sources of extreme ultraviolet photons.

### SUMMARY

A plasma chamber according to the present teaching, which can be a plasma chamber for an ultraviolet light source, includes a plasma generation region that defines a plasma confinement region. A port is positioned adjacent to a side of the plasma generation region that allows generated ultraviolet radiation to pass out of the chamber. A gas feed port can be positioned proximate to the plasma generation region. A vacuum pump port can be positioned proximate to the plasma generation region.

A high voltage region is coupled to the plasma generation region. A grounded region is coupled to the high voltage region that defines an outer surface configured to be coupled to the ground and is dimensioned for receiving a surrounding inductive core. A width of the high voltage region is greater than the width of the grounded region. In various embodiments, a width of the high voltage region can be at least two times greater than the width of the grounded region. A width of the plasma generation region can also be less than the width of the grounded region.

An insulated region can be coupled to the grounded region and can be configured to be coupled to ground potential. The insulating region may also have an aperture for passing ultraviolet light. The insulated region can be configured to reduce negative potential proximate to the grounded region to reduce the attraction of ions generated in the plasma generation region. A gas feed port for providing gas to the plasma generation region can be positioned in the insulating region. A plasma diagnostic port can also be positioned in the insulating region. A port in the insulated region can include an aperture for passing ultraviolet light.

A mirror can be positioned adjacent to the grounded region that is oriented to reflect at least some light generated in the plasma generation region back to the plasma generation region. The mirror can be partially transmitting so that some light generated in the plasma passes through an output port.

An inner inductive core can be positioned around the plasma generation region to couple current into a plasma loop. An outer inductive core can be positioned around the inner inductive core. An inductive core can be positioned around a portion of the grounded region and configured to prevent current flow in the grounded region.

### BRIEF DESCRIPTION OF THE DRAWINGS

The present teaching, in accordance with preferred and exemplary embodiments, together with further advantages thereof, is more particularly described in the following detailed description, taken in conjunction with the accompanying drawings. The skilled person in the art will understand that the drawings described below are for illustration purposes only. The drawings are not necessarily to scale; emphasis is instead generally being placed upon illustrating principles of the teaching. The drawings are not intended to limit the scope of the Applicant's teaching in any way.

FIG. 1 illustrates a plasma chamber according to the present teaching for a Z-pinch ultraviolet light source.

FIG. 2A illustrates an ultraviolet light source that includes a plasma confinement region, high voltage region, grounded region, and insulating region according to the present teaching.

FIG. 2B illustrates graphs from an oscilloscope that show the pulse operation of an embodiment of an ultraviolet light source of the present teaching.

FIG. 3 illustrates an embodiment of an ultraviolet light source according to the present teaching that includes a gas feed port coupled to the insulating region.

FIG. 4A illustrates an embodiment of an ultraviolet light source according to the present teaching that includes a diagnostic probe port coupled to the insulating region.

FIG. 4B illustrates another embodiment of an ultraviolet light source according to the present teaching that includes a laser source having an output that is optically coupled to the insulating region.

FIG. 5 illustrates an embodiment of an ultraviolet light source according to the present teaching that includes a port comprising a transparent region for passing generated ultraviolet light coupled to the insulating region.

FIG. 6 illustrates an embodiment of an ultraviolet light source according to the present teaching that includes a mirror for reflecting generated ultraviolet light back into the plasma confinement region.

### DESCRIPTION OF VARIOUS EMBODIMENTS

The present teaching will now be described in more detail with reference to exemplary embodiments thereof as shown in the accompanying drawings. While the present teaching is described in conjunction with various embodiments and examples, it is not intended that the present teaching be limited to such embodiments. On the contrary, the present teaching encompasses various alternatives, modifications, and equivalents, as will be appreciated by those of skill in the art. Those of ordinary skill in the art having access to the teaching herein will recognize additional implementations, modifications, and embodiments, as well as other fields of use, which are within the scope of the present disclosure as described herein.

Reference in the specification to “one embodiment” or “an embodiment” means that a particular feature, structure, or characteristic described in connection with the embodiment is included in at least one embodiment of the teaching. The appearances of the phrase “in one embodiment” in various places in the specification are not necessarily all referring to the same embodiment.

It should be understood that the individual steps of the method of the present teaching can be performed in any order and/or simultaneously as long as the teaching remains operable. Furthermore, it should be understood that the apparatus and method of the present teaching can include any number or all of the described embodiments as long as the teaching remains operable.

Extreme ultra-violet light sources play an important role in numerous optical measurement and exposure applications. It is desirable that these sources be configured to accommodate numerous use cases. One challenge is to generate high power and high brightness EUV light in a configuration that allows integration with numerous applications and also exhibits high stability and high reliability.

Extreme ultraviolet radiation is referred to in numerous ways by those skilled in the art. Some skilled in the art sometimes referred to extreme ultraviolet radiation as high-energy ultraviolet radiation, which can be abbreviated as XUV. Extreme ultraviolet radiation generally refers to electromagnetic radiation that is part of the electromagnetic spectrum nominally spanning wavelengths from 124 nm to 10 nm. There is some overlap between extreme ultraviolet radiation and what is considered to be the optical spectrum. One particular EUV wavelength of interest is 13.5 nm because that wavelength is commonly used for lithography. Extreme ultraviolet radiation sources, according to the present teaching, are not limited to the generation of EUV radiation. As is known in the art, plasmas can be used to generate a wide spectral range of photons. For example, plasmas generated according to the present teaching can also be used to generate soft x-ray photons (SXR). This includes, for example, photons with wavelengths of less than 10 nm.

So called Z-pinch plasmas, which have current in the axial direction, have been shown to be effective at producing EUV and SXR light. However, most known sources have employed electrodes to conduct high discharge currents into the plasma. These electrodes, which are typically in contact with high temperature plasma, can melt and produce significant debris, which is highly undesirable as it can greatly reduce the useful lifetime of the source.

Electrodeless approaches to generated EUV are desirable and would fill a considerable market need. Such sources are available, for example, from Energetiq, a Hamamatsu Company, located in Wilmington, MA. These sources are based on a Z-pinch plasma, but avoid electrodes entirely by inductively coupling current into the plasma. The plasma in these EUV sources is magnetically confined away from the source walls, minimizing the heat load and reducing debris and providing excellent open-loop spatial stability, and stable repeatable power output. One challenge with known Z-pinch plasma chambers is that the high voltage region of the chamber walls obscures one side (referred to herein as the backside) of the Z-pinch region. This makes modifying the chamber to provide backside access difficult to impossible because there is no way to achieve ground potential in the high voltage region while the plasma is running.

One feature of the EUV sources of the present teaching is that they are versatile and support various applications. For example, the EUV source operating conditions are user-adjustable. In particular, EUV sources of the present teaching improve upon known Z-pinch designs because they can be optimized for peak power or for peak brightness as required by the user for a particular application. Plasma size can be typically below 1 mm in diameter under typical operating conditions. The design supports a simple and flexible optical interface provided to the user on one side of the system enclosure to connect to the application equipment. Custom interfaces can also be accommodated for particular applications.

Another feature of the EUV sources of the present teaching is that they accommodate two-sided optical access to the plasma chamber. This feature is provided, at least in part, by appropriate modifications to the high-voltage chamber used to generate the Z-pinch system condition.

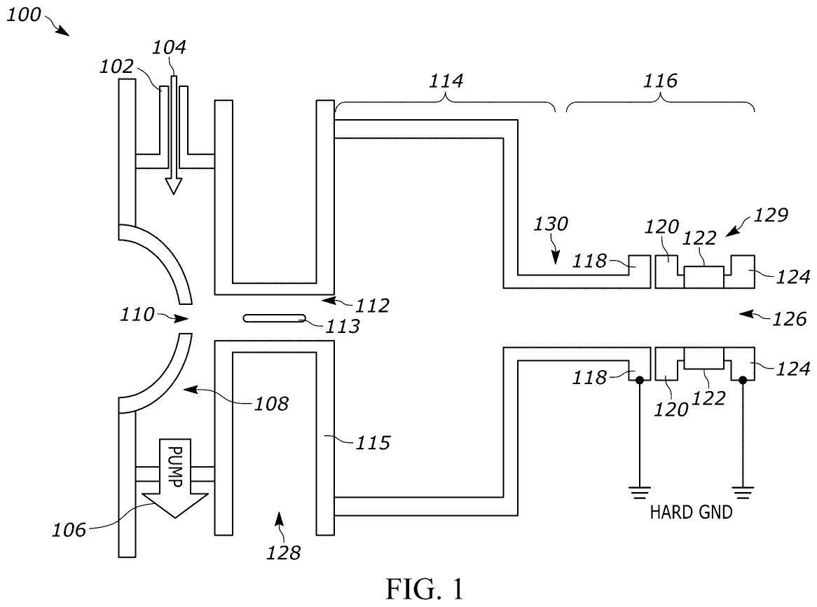

FIG. 1 illustrates a plasma chamber 100 according to the present teaching for a Z-pinch ultraviolet light source. The chamber 100 includes an interface 102 that passes a target gas 104 into the chamber 100. A pump 106 is used to evacuate the chamber region 108 to a desired operating pressure and/or to control gas flow in the chamber 100.

A port 110 is provided to pass EUV radiation generated by the plasma. The port 110 can include a EUV output port that passes the desired EUV radiation. The port 110 can also be configured to include a filter structure that blocks undesired radiation. In some embodiments, the port 110 is configured to be opaque to visual light. For example, in various embodiments, the EUV transparent port 110 is an aperture that can include a spectral purifying foil. Typically, the port 110 is a beam-line aperture port that passes radiation propagating along the beamline. The port can also be configured to have a desired diameter so as to physically block light propagating in certain directions. Furthermore, the diameter of the aperture can be chosen to provide a desired pressure differential.

In various systems, the port 110 is configured to be adaptable for the user to attach to an application system (not shown) where the EUV radiation passes directly through the port 110. A plasma generation region 112 defines a plasma confinement region 113, described in more detail below, using magnetic induction. The plasma confinement region 113 is formed by a pulse forming and power delivery section 115, which carries a current that energizes cores (not shown) in operation. A high voltage region 114 is attached to the plasma generation region 112.

A grounded region 116 is attached to the high voltage region 114. The grounded region 116 has an outer surface that is coupled to ground at a first location 118. An insulating vacuum pipe 120 that includes an insulting break 122 is positioned adjacent to the first location 118. The insulating material forming the insulating break 122 can be formed of a ceramic or one or more other high temperature insulating materials like Polytetrafluoroethylene (PTFE) or similar materials. The vacuum pipe 120 is grounded at position 124 after the insulating break 122 near an input/output port 126 of the chamber 100. The insulating vacuum pipe 120 serves to provide an insulating break that reduces the negative potential to attract ions to further downstream components (not shown) in operation as desired.

The chamber 100 also includes regions 128, 130 to position magnets that provide inductive current flow for the chamber 100 in operation. The end of the region, first location 118, of the chamber 100 is also grounded. Together, the grounded insulating vacuum pipe 120 with insulating break 122 and grounded region 124 at the output port 126 can be referred to as an insulating region 129. One feature of the insulating region 129 of the chamber described herein is that it provides a safe, grounded, external region of the chamber that allows access by users and/or other downstream equipment from the outside of the chamber 100.

One feature of the present teaching is that the input/output port 126 defined by the insulating vacuum pipe 120 is configured for flexible connection of various downstream components (not shown). This feature supports various custom and semi-custom configurations of the chamber 100 to address different applications. For example, the input/output port 126 can form a gas feed port that provides gas to the plasma generation region 112. The input/output port 126 can form a plasma diagnostic port. This allows, for example, optical imaging, spectroscopy and/or electronic probing of the plasma in the plasma generation region 112 from the input/output port 126 during operation. The input/output port 126 can form an aperture for passing ultraviolet light that is generated from the plasma. The input/output port 126 can include a mirror positioned adjacent to the ground position 124. The mirror (not shown) can be fully or partially reflective and is oriented as desired to reflect at least some light generated in the plasma generation region 112 back to the plasma generation region 112. In some embodiments, the mirror is partially transmitting so that some light generated in the plasma generation region 112 passes through the input/output port 126, and some light is reflected back. In some embodiments, this light is EUV radiation generated in the plasma generation region, and in some embodiments this light can also include, for example, laser light or other light that interacts with and/or probes the plasma.

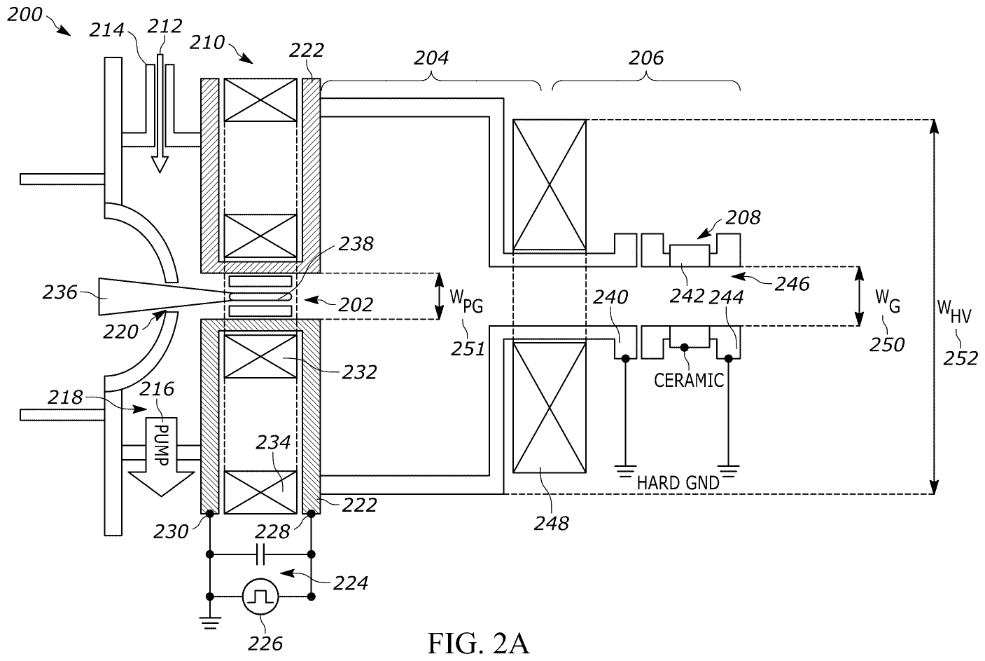

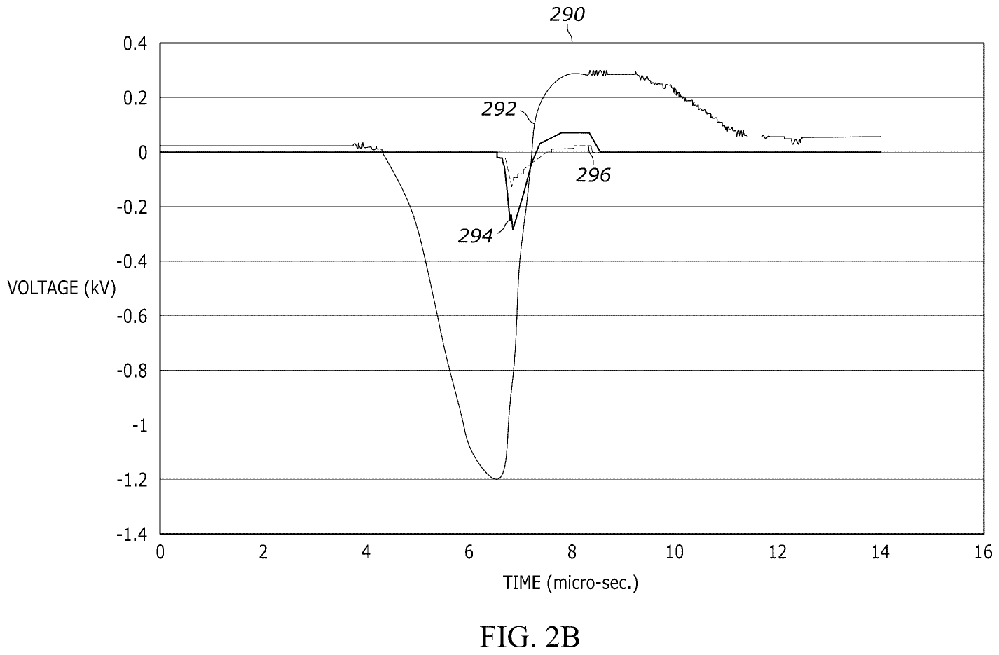

FIG. 2A illustrates an ultraviolet light source 200 that includes a plasma confinement region 202, high voltage region 204, grounded region 206, and an insulating region 208, according to the present teaching. The source 200 is an inductive design that uses magnetic confinement of the plasma in the plasma confinement region 202 away from the components of the chamber 210 to provide high reliability and high stability. A target gas 212 enters through an interface 214 into the chamber 210. In some embodiments, the target gas is Xenon. A pump 216 is used to evacuate the chamber region 218 to a desired operating pressure. A port 220 is provided to pass EUV radiation, that is, EUV light 236 generated by the plasma.

A pulse forming and power delivery section 222 is driven using a parallel connected capacitor 224 and pulse generator 226 that drives a current to flow through the section 222 to the ground. The pulse generator 226 applies negative high-voltage pulses across the capacitor. In some embodiments, the capacitor 224 is a bank of multiple capacitors. Thus, the pulse forming and power delivery section 222 of the chamber 210 has a high voltage side 228 and a ground side 230. An inner magnetic core 232 and an outer magnetic core 234, energized by the current pulses flowing through pulse forming and power delivery section 222, generate at least three inductively coupled plasma loops (not shown) that converge in the plasma generation region 202 that forms a magnetically confined Z-pinch. The loops flow through the region between the inner core 232 and outer core 234 and through the plasma generation region 202.

In operation, the voltage pulse from the pulse generator 226 charges the capacitor 224. During the charging time, the small leak current from the cores 232, 234 sustains the plasma loop. The pinch operation requires a sustained loop, because it requires ionized gas for proper function. The outer core 234 saturates, driving the impedance to zero. The capacitor then discharges. This results in beneficial pulse compression. The inner core 232 couples the current pulse to the plasma loops, resulting in a large pulse in plasma current known as the Z-pinch.

The plasma generation region 202 produces and emits nearly 100% of the EUV radiation produced by the plasma. The plasma loops do not produce EUV light. The result is that the source 200 produces a high quality, relatively compact source of EUV light 236 from a well-defined and stable pinch plasma confinement region 238 within the plasma generation region 202. By using the pulse forming and power delivery section 222 to drive and contain the plasma, the source 200 operates without the use of electrodes that are commonly used to conduct discharge current to the plasma in known systems.

Known Z-pinch plasma chambers have electrical continuity between the high voltage region 204 and the plasma generation region 202. Consequently, when the outside of the chamber 210 is at a high potential voltage, it is difficult or impossible to have back-side access to the chamber.

In contrast, with the configuration shown in FIG. 2A, the high voltage region 204 is electrically connected to the high voltage side 228 of the pulse forming and power delivery section 222, while the grounded region 206 is coupled to the high voltage region 204. In particular, the grounded region 206 has an outer surface that is coupled to ground at a first location 240. Furthermore, there is an insulating vacuum pipe in the insulating region 208 which includes an insulating break 242. With this configuration, the insulating region 208 is grounded at position 244 after the insulating break 242 near an output 246 of the chamber 210. The result is that the insulating region 208 serves to provide an insulating break that reduces the negative potential that attracts ions to further downstream components in operation as desired.

A current preventing inductive core 248 is positioned at the boundary between the high voltage region 204 and the grounded region 206 of the chamber 210. The hard ground connected to positions 240, 244 in the ground region 206 and the ground connected to the ground side 230 are electrically connected. A bias electric current is applied to the current preventing inductive core 248. This bias electric current reduces the current flow from the high voltage region 204 into the grounded region 206.

In operation, some pulsed leak current flows along the pipe (118 or 240) proximate to the end of the chamber through inductive core 248. The time-change of the current on the pipe (118, 240) gives a time-change of magnetic flux flowing in a circumferential direction of the core 248. The time-change of the magnetic flux causes an inverse current to flow on the pipe (118 or 240) proximate to the end of the chamber. Consequently, the leak current is canceled by the resulting induced current thereby preventing the leak current from flowing further. As the voltage at the high voltage side 228 swings from negative to positive, the current preventing core 248 is then reset automatically.

Various embodiments can use different dimensions of elements in the chamber 210. In general, a width 250, W_{G}, of the grounded region is greater than a width 251, W_{PG}, of the plasma generation region 202. In some embodiments, the cross-section area perpendicular to magnetic flux in the current preventing core 248 of the current preventing inductive core 248 is larger than the inner core 232. In some embodiments, the cross-section area of the current preventing inductive core 248 is at least twice the cross-section area of the inner core 232. In this case, a width 252, W_{HV}, of the high voltage region is greater than the width 250, W_{G}, of the grounded region. In some configurations, a width 252, W_{HV}, of the high voltage region is at least twice the width 250, W_{G}, of the grounded region.

The input/output port 246, like the input/output port 126 described in connection with FIG. 1, can be configured for versatile connection of various downstream components to support custom and semi-custom configurations of the source 200 to address numerous different applications. The generated EUV radiation 236 can also be directed at the backside of the pinch confinement region 238 (back side EUV radiation not shown). The output 246 can be configured to collect this back-side EUV radiation and project it to downstream components. For example, the input/output port 246 can be configured to enhance the EUV radiation using a multilayer mirror at the output. The input/output port 246 can also be used for optical access and gas fueling purposes. All or some of these configurations of the input/output port 246 can be combined as well. Some of these configurations are described in more detail below.

For example, in one particular embodiment, the source 200 is configured to produce about twenty Watts of 13.5-nm-wavelength EUV radiation in 2-pi steradians with a brightness of eight W/mm²-sr. The source radiation can be pulse at relatively high, such as about 2.5 kHz, and the rate can be user configurable. The plasma confinement region 238 for such a source can be less than 1 mm in diameter, or even can be less than 0.5 mm in diameter. In some methods of operation, the actual position of the plasma confinement region 238 varies by less than a few microns pulse-to-pulse.

FIG. 2B illustrates graphs 290 from an oscilloscope that shows the pulse operation of an embodiment of an ultraviolet light source of the present teaching. The first trace 292 illustrates the capacitor discharge used to create the Z-pinch plasma. The second trace 294 illustrates the voltage measured at pipe position 240 (FIG. 2A) to ground. These voltages are both large, negative high-voltage swings of 500 V and greater. The third trace 296 is the voltage measured at pipe position 244 (FIG. 2A) to ground.

Thus, the configuration described in FIG. 2A reduced the leakage voltage at pipe position 244 down to relatively low voltage levels that are safe for the operator to maintain and reconfigure. The plasma current flows only when the voltage swings from low to high, so the main current pulse is always in the same direction. While the capacitor voltage does swing positive, the negative voltage is always larger, so the current preventing inductive core 248 is negatively charged after each pulse, and can be reset by a positive applied voltage.

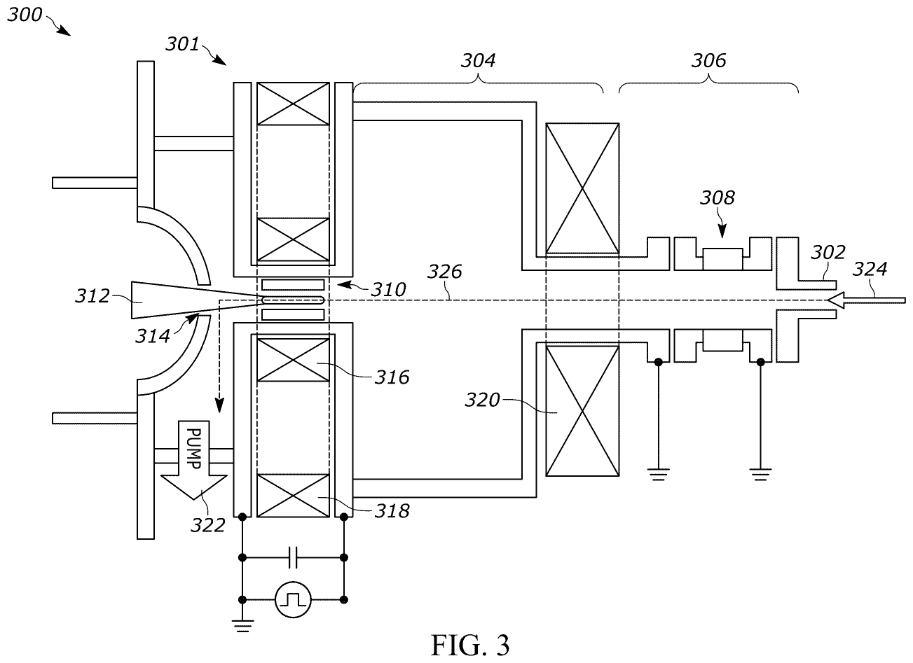

FIG. 3 illustrates an embodiment of an ultraviolet light source 300 according to the present teaching that includes a gas feed port 302 coupled to the insulating region 308. Similar to the source 200 described in connection with FIG. 2A and the chamber 100 described in connection with FIG. 1, the source 300 includes many common components including a chamber 301, high voltage region 304, grounded region 306, insulating region 308, plasma confinement region 310, a port 314 for passing EUV radiation 312, an inner core 316, outer core 318, current preventing core 320, and pump 322.

A gas 324 is fed through the gas feed port 302 into the chamber 301 to the plasma confinement region. In some embodiments the gas 324 is Xenon gas. The gas 324 flows through the chamber 301 and out the pump 322 as illustrated by the dashed line 326. In some embodiments, the gas feed port 302 supports the insertion of a gas jet that delivers gas 324 to the plasma generation region. One advantage of attaching a gas feed port 302 to the insulating region 308 is that is such a configuration improves fueling of the plasma created in the plasma confinement region 310. This improvement can lead to higher plasma density which can result in a higher power and/or higher brightness of the EUV radiation 312. In some embodiments, the gas feed port 302 is the only gas port in the chamber 301. In some embodiments, more than one gas port is used.

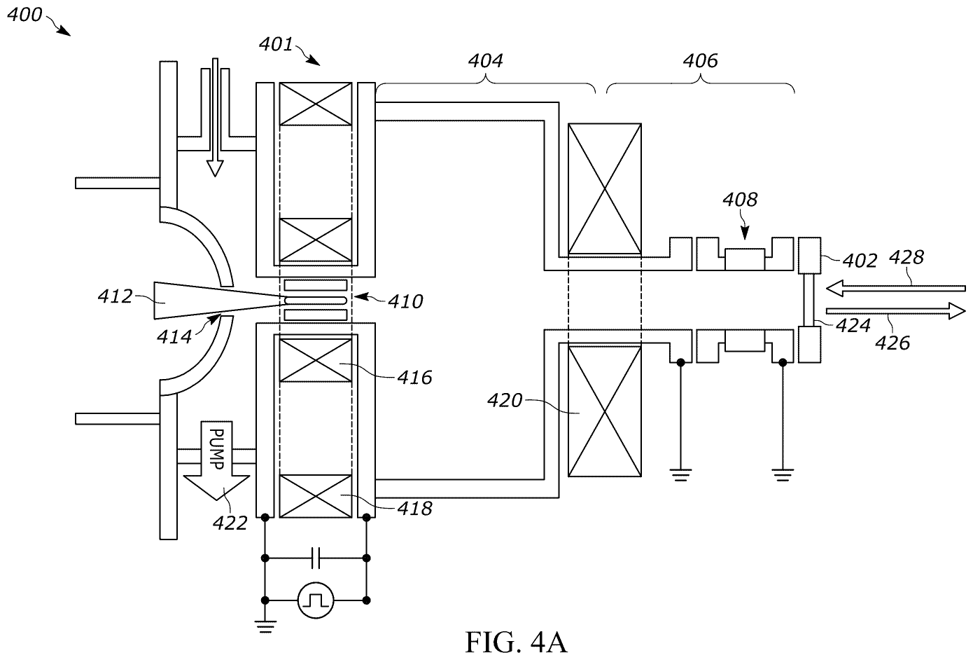

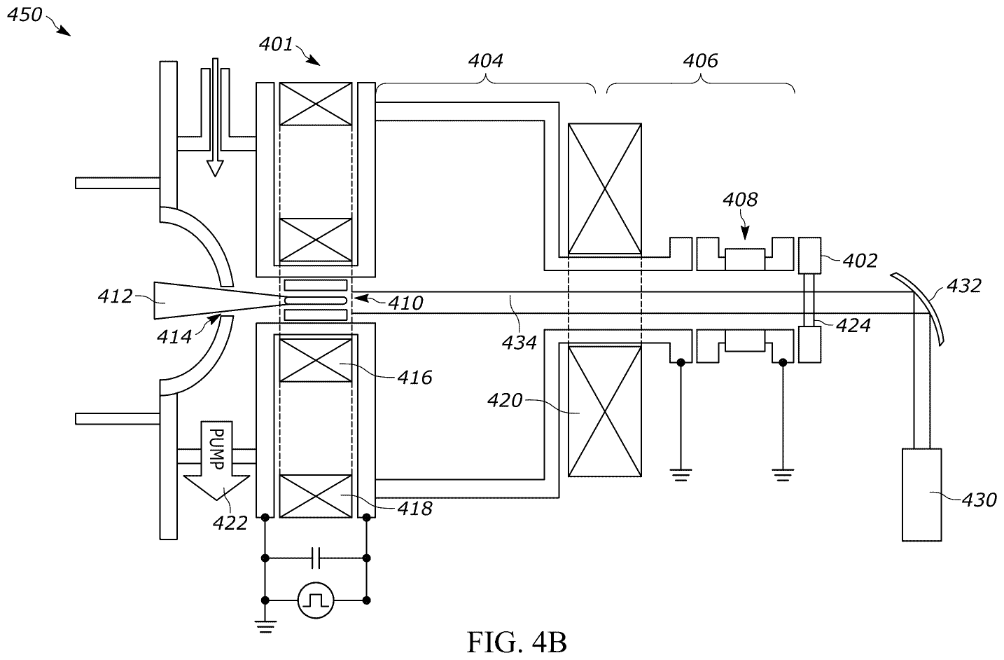

FIG. 4A illustrates an embodiment of an ultraviolet light source 400 according to the present teaching that includes a diagnostic probe port 402 coupled to the insulating region 408. Similar to the source 200 described in connection with FIG. 2A and the chamber 100 described in connection with FIG. 1, the source 400 includes many common components including a chamber 401, high voltage region 404, grounded region 406, insulating region 408, a plasma confinement region 410, a port 414 that passes EUV radiation 412, an inner core 416, outer core 418, current preventing core 420, and pump 422.

The diagnostic probe port 402 includes an optical port 424. The optical port 424 passes light 426 collected from the back-side of the plasma generation region 410. This light 426 can help detect plasma properties, including, for example, optical output power as a function of position and/or time. The port 424 can also pass probe light 428 into the chamber 401. The probe light 428 can be directed into the plasma confinement region and the resulting light 426 collected from the back-side of the plasma generation region 410 that returns to the port 424 can be detected to determine various plasma properties. The probe light 428 can also be used for numerous other purposes, such as to determine the properties of the gas. One feature of the chambers according to the present teaching is that it is highly desirable to have the optical port 424 at ground potential for safety reasons.

FIG. 4B illustrates another embodiment of an ultraviolet light source 450 according to the present teaching that includes a laser source 430 having an output optically coupled to the insulating region 408 so that light passes through the chamber into the plasma confinement region. Similar to the source 200 described in connection with FIG. 2A, the chamber 100 described in connection with FIG. 1, and the source 400 described in connection with FIG. 4A, the source 450 includes many common components, including the chamber 401, high voltage region 404, grounded region 406, insulating region 408, plasma confinement region 410, port 414 that passes EUV radiation 412, inner core 416, outer core 418, current preventing core 420, and the pump 422.

Like the configuration described in connection with FIG. 4A, the diagnostic probe port 402 includes an optical port 424 that passes radiation with a desired frequency. The optical port can include a filter to pass only the desired radiation. The optical port 424 in FIG. 4B is generally configured to pass laser radiation generated by the laser 430. Additionally, the optical port 402 can be used for diagnostic purposes to detect properties and/or to probe the plasma as described in connection with FIG. 4A.

Laser optics 423 are positioned relative to the output of the laser 430 to direct laser radiation generated by the laser 430 into the plasma confinement region. For example, the laser optics 432 can be a mirror or collection of mirrors as shown that directs laser radiation from the output of the laser 430 to the plasma confinement region. In other embodiments, the laser optics 430 can include a transmissive lens that passes and focuses the laser radiation into the plasma confinement region. In various embodiments, the laser 430 generates sufficient power at the desired wavelength that heats the plasma to form a Z-pinched plasma. As described in connection with the configuration of FIG. 4A, one feature of the chambers is that it includes the optical port 424 at ground potential for safety reasons.

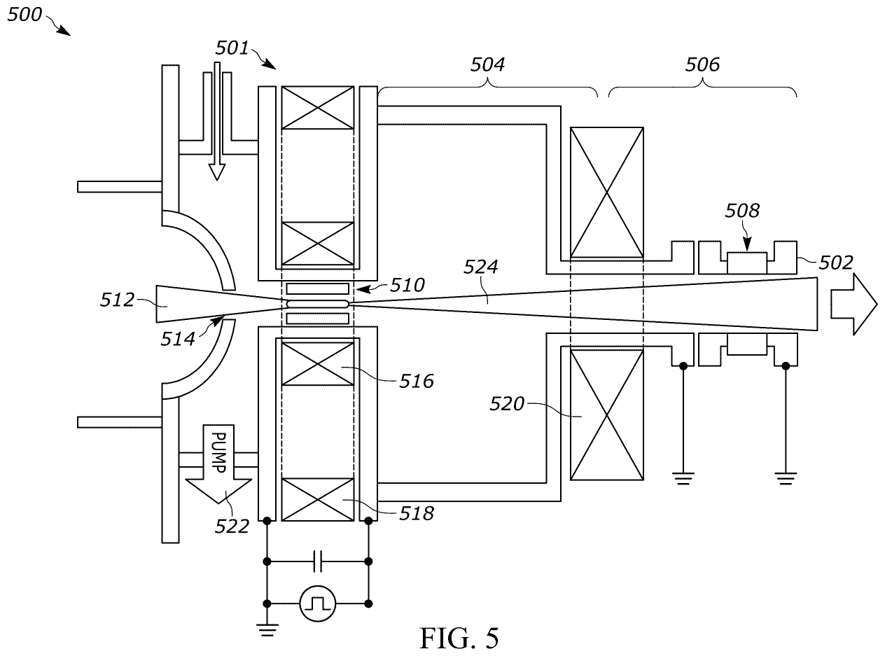

FIG. 5 illustrates an embodiment of an ultraviolet light source 500 according to the present teaching that includes a port 502 having a transparent region for passing generated ultraviolet light coupled to the insulating region 508. Similar to the source 200 described in connection with FIG. 2A and the chamber 100 described in connection with FIG. 1, the source 500 includes many common components including a chamber 501, high voltage region 504, grounded region 506, insulating region 508, plasma confinement region 510, a port 514 for passing EUV radiation 512, an inner core 516, outer core 518, current preventing core 520, and pump 522.

The port 502 is configured to pass EUV radiation 524 generated in the plasma generation region 510 from the back-side. The port 502 is also configured to interface with a beamline assembly system, which can be a customer supplied system to the chamber 501. In some embodiments, the system can be a sealed system that interfaces with the port 520 so as to maintain a desired pressure in the chamber during operation. In other embodiments, a transparent port seals the port and light transmits through the port to the attached system. One feature of the source 500 is that EUV radiation emerges as both front-side EUV radiation 512 and back-side EUV radiation 524. This feature allows two systems to be supplied from the same source 500, one with front-side access and one with back-side access. In various embodiments, the two systems can be the same system or different systems.

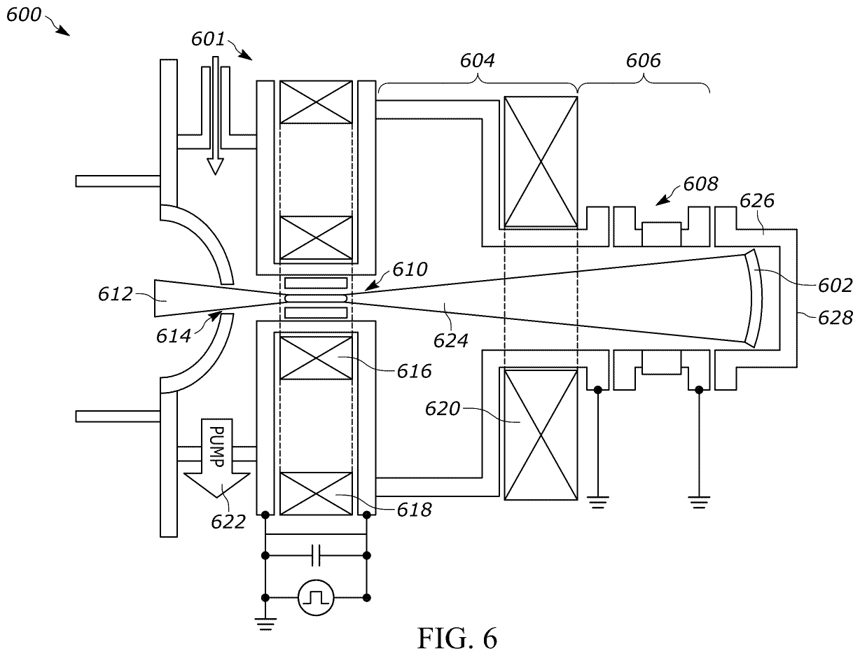

FIG. 6 illustrates an embodiment of an ultraviolet light source 600 according to the present teaching that includes a mirror 602 for reflecting generated ultraviolet light back into the plasma confinement region. Similar to the source 200 described in connection with FIG. 2A and the chamber 100 described in connection with FIG. 1, the source 600 includes many common components including a chamber 601, high voltage region 604, grounded region 606, insulating region 608, a plasma confinement region 610, a port 614 for passing EUV radiation 612, an inner core 616, outer core 618, current preventing core 620, and pump 622. The mirror 602 reflects at least some emitted EUV radiation 624 from the plasma generation region 610 back toward the front of the chamber to co-propagate with the EUV radiation 612 from the front side. In some configurations, the mirror 602 is formed in a parabolic shape or some other curved shape that focuses the reflected light back through the plasma generation region. The mirror 602 can be configured to be highly reflective for EUV radiation 624. In these configurations, the mirror 602 can provide a substantial improvement in the optical power available from the source 600 at the port 614. The improvement can be nearly a factor of two. In other configurations, the mirror 602 is a partially reflecting mirror.

The mirror 602 can be constructed in numerous ways, such as by using a multilayer construction of Molybdenum and Silicon. The mirror 602 can be held and/or positioned by a securing member 626 attached to the insulating region 608. The securing member 626 can include a port that is transparent to the EUV radiation 624.

One feature of the high-voltage chamber configuration for EUV sources according to the present teaching is that it allows for safe and flexible access to one end of a Z-pinch plasma source that emits radiation from the other end. Another feature of the chamber configurations according to the present teaching is that it supports the necessary high-voltage drive protocol and system components that are needed to generate and sustain a Z-pinch and the associated plasma loops using inductive coils to drive the plasma current.

It should be understood that EUV sources according to the present teaching can support a wide array of test and measurement capabilities that can be initially supplied with the source, or that can be added at a later point in the system life cycle. Another advantage of the EUV sources of the present teaching is that they can support highly flexible access to the EUV radiation generated by the plasma that results in many more possible configurations than known EUV systems. In addition, the EUV sources of the present teaching can provide more interaction with and control of the plasma using one or more optical excitation, optical probing, and feed gas management. Furthermore, the EUV sources of the present teaching can support more flexible EUV optical beam shaping and management by incorporating various types of optics within and/or near the back-side access area of the configuration.

One skilled in the art will appreciate that there are numerous methods of generating ultraviolet light according to the present teaching. These methods generally provide a feed gas to a plasma confinement region in a plasma chamber. Some methods also apply gas to a port positioned at one or more of various locations, such as adjacent to the insulating region. A high voltage is applied to a high voltage region connected to the plasma confinement region in the plasma chamber. A grounded region is electrically connected to the high voltage region. A train of voltage pulses is applied to at least one capacitor electrically connected across an outer magnetic core surrounding an inner magnetic core that is positioned around the plasma confinement region. The voltage pulses cause at least one capacitor to charge so that the outer magnetic core saturates resulting in the capacitor(s) discharging causing the inner core to couple current pulses into the plasma confinement region, thereby forming a plasma in a loop where the plasma is sustained between voltage pulses by a leakage current. The plasma generates ultraviolet light that propagates through a transparent port positioned adjacent to the plasma confinement region.

Numerous performance advantages are achieved by providing an insulating region that is grounded and coupled to the grounded region in order to reduce the attraction of ions generated in the plasma loop to the grounded region. An electric current is applied to an inductive core surrounding a portion of the grounded region of the plasma chamber in order to reduce current flow into the grounded region.

In addition, some methods include retro-reflecting a portion of the generated ultraviolet light entering the grounded region back to the plasma generation region to increase the brightness of ultraviolet light passing through the transparent port positioned adjacent to the plasma confinement region. Also, some methods include passing a portion of the generated ultraviolet light entering the grounded region through a transparent port positioned adjacent to the insulating region. Also, some methods include characterizing the generated ultraviolet light passed through the transparent port positioned adjacent to the insulating region. Some methods also pass a diagnostic probe beam through a transparent port positioned adjacent to the insulating region into the plasma generation region. Some methods measure the properties of the plasma in response to the interaction of the diagnostic probe beam and the plasma.

### EQUIVALENTS

While the Applicant's teaching is described in conjunction with various embodiments, it is not intended that the Applicant's teaching be limited to such embodiments. On the contrary, the Applicant's teaching encompasses various alternatives, modifications, and equivalents, as will be appreciated by those of skill in the art, which may be made therein without departing from the spirit and scope of the teaching.

1-32. (canceled)

33. A plasma chamber for a light source, the plasma chamber comprising:
a) a plasma generation region that defines a plasma confinement region;
b) a port positioned adjacent to a first side of the plasma generation region that allows generated light to pass out of the plasma chamber;
and
c) a current preventing inductive core positioned around a portion of the plasma chamber and positioned at a boundary between a high voltage region electrically connected to the plasma generation region and a grounded region of the plasma chamber that is electrically connected to ground potential.

34. The plasma chamber of claim 33, wherein a width of the high voltage region is greater than a width of the grounded region.

35. The plasma chamber of claim 33, wherein the width of the high voltage region is at least two times greater than the width of the grounded region.

36. The plasma chamber of claim 33, wherein a width of the plasma generation region is less than a width of the grounded region.

37. The plasma chamber of claim 33, further comprising an insulated region that is electrically connected to the grounded region.

38. The plasma chamber of claim 37, wherein an end of the insulated region comprises a port.

39. The plasma chamber of claim 38, further comprising a gas feed port positioned in the port at the end of the insulated region, the gas feed port providing gas to the plasma generation region.

40. The plasma chamber of claim 38, wherein the port at the end of the insulated region comprises a plasma diagnostic port.

41. The plasma chamber of claim 38, wherein the port at the end of the insulated region comprises an aperture for passing light.

42. The plasma chamber of claim 33, further comprising a mirror positioned adjacent to the grounded region that is oriented to reflect at least some light generated in the plasma generation region back to the plasma generation region.

43. The plasma chamber of claim 42, wherein the mirror is partially transmitting.

44. The plasma chamber of claim 33, further comprising a gas feed port positioned proximate to the plasma generation region.

45. The plasma chamber of claim 33, further comprising a vacuum pump port positioned proximate to the plasma generation region.

46. A light source comprising:
a) a plasma chamber comprising:
i) a plasma generation region that defines a plasma confinement region;
ii) a port positioned adjacent to the plasma generation region that allows generated light to pass out of the plasma chamber;
iii) a high voltage region coupled to the plasma generation region; and
iv) a grounded region coupled to the high voltage region;
b) an inner inductive core positioned around the plasma generation region that couples current into a plasma loop;
c) an outer inductive core positioned around the inner inductive core; and
d) an inductive core positioned around a portion of the grounded region and configured to prevent current flow in the grounded region.

47. The light source of claim 46 further comprising an insulated region having a first end that is coupled to the grounded region and a second end that is electrically connected to ground potential, the insulated region reducing negative potential proximate to the grounded region to reduce attraction of ions generated in the plasma generation region.

48. The light source of claim 47, wherein the second end of the insulated region comprises a port.

49. The light source of claim 48, further comprising a gas feed port positioned in the port at the second end of the insulated region, the gas feed port providing gas to the plasma generation region.

50. The light source of claim 48, wherein the port at the second end of the insulated region comprises a plasma diagnostic port.

51. The light source of claim 48, wherein the port at the second end of the insulated region comprises an aperture for passing light.

52. The light source of claim 46 wherein a width of the high voltage region is greater than a width of the grounded region.

53. The light source of claim 46, wherein a width of the high voltage region is at least two times greater than a width of the grounded region.

54. The light source of claim 46, wherein a width of the plasma generation region is less than a width of the grounded region.

55. The light source of claim 46, further comprising a mirror positioned adjacent to the grounded region that is oriented to reflect at least some light generated in the plasma generation region back to the plasma generation region.

56. The light source of claim 55, wherein the mirror is partially transmitting so that some light generated in the plasma passes through a port.

57. The light source of claim 46, further comprising a gas feed port positioned proximate to the plasma generation region.

58. The light source of claim 46, further comprising a vacuum pump port positioned proximate to the plasma generation region.
